(19) United States
(12) Patent Application Publication
(10) Pub. No.: US 2015/0263715 A1
(43) Pub. Date: Sep. 17, 2015

(54) ACTIVE NOISE FILTER AND GATE DRIVING DEVICE HAVING THE SAME

(71) Applicant: SAMSUNG ELECTRO-MECHANICS CO., LTD., Suwon-Si (KR)

(72) Inventor: Jun Ho Lee, Suwon-Si (KR)

(21) Appl. No.: 14/622,735

(22) Filed: Feb. 13, 2015

(30) Foreign Application Priority Data
Mar. 17, 2014 (KR) 10-2014-0030942

(51) Int. Cl. H03K 5/1252; H03K 17/687; H03K 3/013

(52) U.S. Cl. CPC H03K 5/1252; H03K 3/013; H03K 17/687

(57) ABSTRACT

A gate driving device may include an active noise filter unit configured to filter noise included in an input signal and correct the filtered input signal based on a level of the filtered input signal, a level shift unit configured to convert a level of the corrected input signal to a preset level, and a gate driving unit configured to output a switching control signal based on the converted input signal.

### CROSS-REFERENCE TO RELATED APPLICATION

This application claims priority to, and benefit of, Korean Patent Application No. 10-2014-0030942 filed on Mar. 17, 2014, with the Korean Intellectual Property Office, the disclosure of which is incorporated herein by reference.

### BACKGROUND

The present disclosure relates to an active noise filter and a gate driving device having the same.

In general, a gate driving device may be used in an inverter which outputs alternating current (AC) power in order to drive a motor, or the like, and may include a noise filter in an input terminal thereof in order to remove noise included in an input signal.

A noise filter used in a conventional gate driving device may include a resistor and a capacitor and may compare a pulse width of the input signal with a preset reference time in order to remove a signal having a pulse width lower than the preset reference time, thereby filtering noise.

However, in the case of a conventional noise filter, when noise, that is, a signal having a pulse width lower than a reference time is input to a conventional noise filter, such a conventional noise filter may output unfiltered noise due to overlapping input signals.

In the case in which a signal having a pulse width lower than a reference time is continuously input, since a gate driving unit may be maintained in a high state in such a case, an over-current may occur, resulting in the breakdown of an inverter.

### SUMMARY

An exemplary embodiment in the present disclosure may provide an active noise filter capable of filtering noise by preventing input signals from overlapping, even in the case in which the input signals are continuously input, by correcting a level of the input signal based on the level of the input signal, and a gate driving device having the same.

According to an exemplary embodiment in the present disclosure, a gate driving device may include: an active noise filter unit filtering noise included in an input signal and correcting the filtered input signal based on a level of the filtered input signal; a level shift unit converting a level of the corrected input signal to a preset level; and a gate driving unit outputting a switching control signal based on level of the converted input signal.

The active noise filter unit may include: a filter unit filtering noise included in the input signal; and a signal correcting unit correcting the filtered input signal based on a level of the filtered input signal.

The signal correcting unit may output a high signal in a case in which the level of the filtered input signal is higher than a level of a preset reference voltage, and may output a low signal in a case in which the level of the filtered input signal is lower than the level of the preset reference voltage.

The signal correcting unit may include: a first transistor having the filtered input signal provided to a gate thereof, and switched on in a case in which the level of the filtered input signal is higher than a level of the preset reference voltage; and a second transistor coupled to the first transistor in a cascode manner, having the filtered input signal provided to a gate thereof, and switched off in the case in which the level of the filtered input signal is higher than the level of the preset reference voltage.

The signal correcting unit may include a comparator comparing the level of the filtered input signal with a level of a preset reference voltage.

The active noise filter unit may further include a first buffer connected between a signal input terminal and the filter unit.

The active noise filter unit may further include a second buffer connected between the signal correcting unit and the level shift unit.

The filter unit may be a resistor-capacitor (RC) filter.

According to an exemplary embodiment in the present disclosure, an active noise filter may include: a filter unit filtering noise included in an input signal; and a signal correcting unit correcting the filtered input signal based on a level of the filtered input signal.

The signal correcting unit may output a high signal in a case in which the level of the filtered input signal is higher than a level of a preset reference voltage, and may output a low signal in a case in which the level of the filtered input signal is lower than the level of the preset reference voltage.

The signal correcting unit may output a high signal in a case in which the level of the filtered input signal is higher than a level of the preset reference voltage, and may output a low signal in a case in which the level of the filtered input signal is lower than the level of the preset reference voltage.

The signal correcting unit may include: a first transistor having the filtered input signal provided to a gate thereof, and switched on in the case in which the filtered input signal is higher than the level of the preset reference voltage; and a second transistor coupled to the first transistor in a cascode manner, having the filtered input signal provided to a gate thereof, and switched off in the case in which the level of the filtered input signal is higher than the level of the preset reference voltage.

The signal correcting unit may include a comparator comparing the level of the filtered input signal with the level of the preset reference voltage.

The active noise filter unit may further include a first buffer connected between a signal input terminal and the filter unit.

The active noise filter unit may further include a second buffer connected between the signal correcting unit and a signal output terminal.

The filter unit may be an RC filter.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a configuration diagram illustrating an example of a gate driving device according to an exemplary embodiment in the present disclosure;

FIG. 2 is a configuration diagram illustrating an example of an active noise filter unit illustrated in FIG. 1;

FIG. 3 is a diagram illustrating an example of a signal correcting unit illustrated in FIG. 2;

FIG. 4 is a diagram illustrating another example of the signal correcting unit illustrated in FIG. 2;

FIG. 5 is a diagram illustrating another example of the active noise filter unit illustrated in FIG. 1; and

FIG. 6 is a graph illustrating a corrected input signal according to an exemplary embodiment in the present disclosure.

### DETAILED DESCRIPTION

Hereinafter, embodiments in the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

Throughout the drawings, the same or like reference numerals will be used to designate the same or like elements.

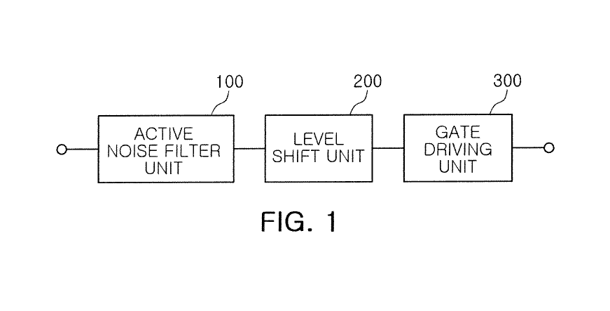

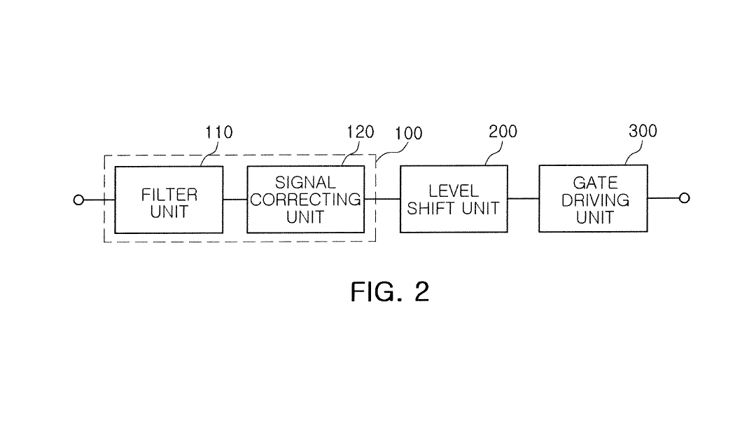

FIG. 1 is a configuration diagram illustrating an example of a gate driving device according to an exemplary embodiment in the present disclosure, and FIG. 2 is a configuration diagram illustrating an example of an active noise filter unit illustrated in FIG. 1.

Referring to FIGS. 1 and 2, a gate driving device according to an exemplary embodiment in the present disclosure may include an active noise filter unit 100, a level shift unit 200, and a gate driving unit 300.

The active noise filter unit 100 may remove noise included in an input signal input to a signal input terminal.

Here, the input signal may be a pulse-width modulation (PWM) signal. In addition, in a case in which noise is continuously input, in order to prevent noise from being misrecognized as the input signal due to such overlapping noise, the active noise filter unit 100 may correct a level of a filtered input signal based on a level of the input signal.

According to the exemplary embodiment in the present disclosure, the active noise filter unit 100 may include a filter unit 110 filtering noise included in the input signal, and a signal correcting unit 120 correcting the level of the filtered input signal.

According to the exemplary embodiment in the present disclosure, the filter unit 110 may be a resistor-capacitor (RC) filter.

In addition, the signal correcting unit 120 may output a high signal in a case in which a level of the filtered input signal is higher than a level of a preset reference voltage, and may output a low signal in a case in which the level of the filtered input signal is lower than the level of the preset reference voltage.

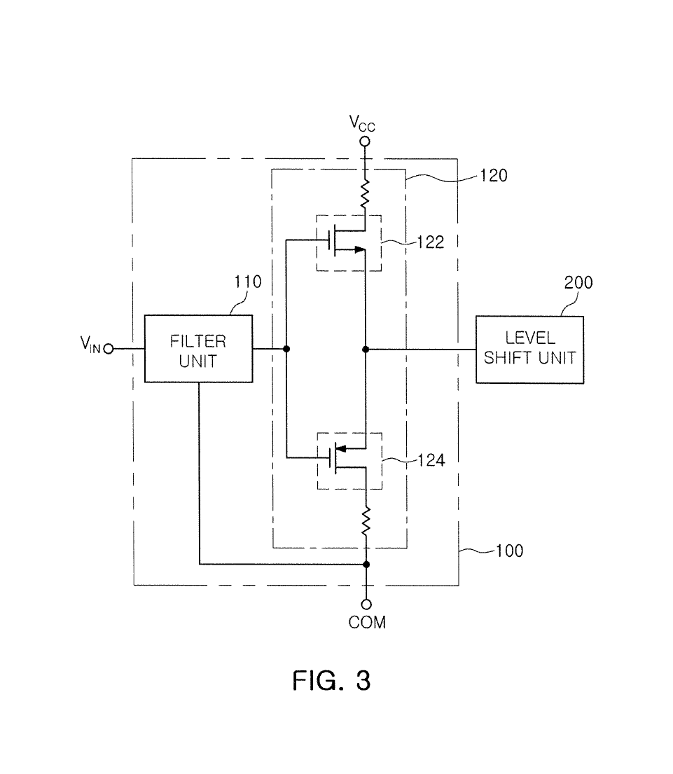

A detailed description thereof will be provided below with reference to FIGS. 3 through 5.

The level shift unit 200 may increase the level of the input signal filtered by the active noise filter unit 100 in order to allow the gate driving unit 300 to be driven, and may transfer the increased level of the input signal to the gate driving unit 300.

The gate driving unit 300 may output a switching control signal based on the level of the input signal converted by the level shift unit 200.

The gate driving device including the active noise filter unit 100, the level shift unit 200, and the gate driving unit 300 as described above may be used for an inverter for driving a motor, or the like.

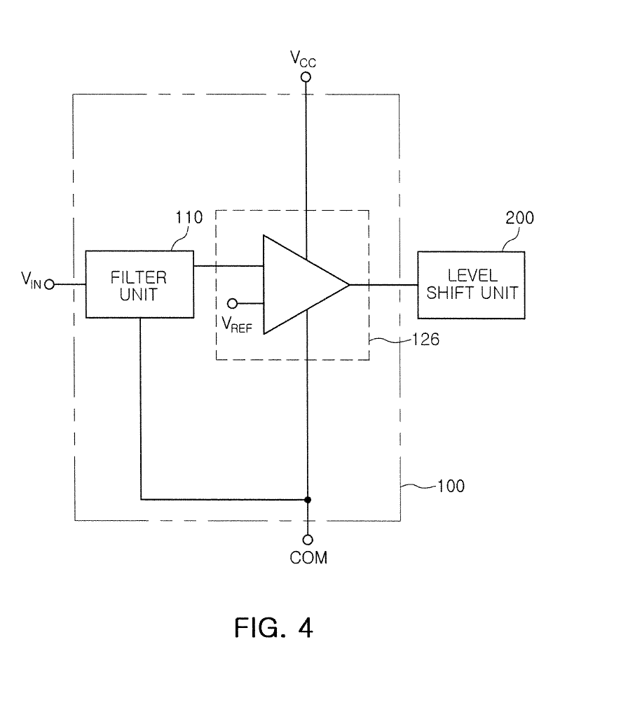

FIG. 3 is a diagram illustrating an example of a signal correcting unit illustrated in FIG. 2, and FIG. 4 is a diagram illustrating another example of the signal correcting unit illustrated in FIG. 2.

Referring to FIG. 3, the signal correcting unit 120 according to an exemplary embodiment in the present disclosure may include a first transistor 122 and a second transistor 124.

A gate of the first transistor 122 may be provided with an input signal filtered by the filter unit 110, a drain thereof may be connected to a power source Vcc, and a source thereof may be connected to the level shift unit 200.

The first transistor 122 may be switched on in a case in which a level of the filtered input signal is higher than a level of a preset reference voltage, and may be switched off in a case in which the level of the filtered input signal is lower than the level of the preset reference voltage.

The second transistor 124 may be coupled to the first transistor 122 in a cascode manner. In detail, a source of the second transistor 124 may be connected to the source of the first transistor 122.

In addition, the second transistor 124 may have a gate to which the filtered input signal is provided, may be switched off in the case in which the level of the filtered input signal is higher than the level of the preset reference voltage, and may be switched on in the case in which the level of the filtered input signal is lower than the level of the preset reference voltage.

That is, in the case in which the level of the input signal provided from the filter unit 110 is higher than the level of the preset reference voltage, the first transistor 122 may be switched on and the second transistor 124 may be switched off, such that the signal correcting unit 120 may correct a rising curve of the filtered input signal in a vertically increasing manner. Conversely, in the case in which the level of the input signal provided from the filter unit 110 is lower than the level of the preset reference voltage, the first transistor 122 may be switched off and the second transistor 124 may be switched on, such that the signal correcting unit 120 may correct a falling curve of the filtered input signal in a vertically decreasing manner.

According to an exemplary embodiment in the present disclosure, the signal correcting unit 120 may include a comparator 126 comparing the level of the input signal filtered by the filter unit 110 with a level of a preset reference voltage Vref, as illustrated in FIG. 4.

Here, the comparator 126 may output a high signal in the case in which the level of the filtered input signal is higher than the level of the preset reference voltage, and may output a low signal in the case in which the level of the filtered input signal is lower than the level of the preset reference voltage, thereby correcting the level of the input signal.

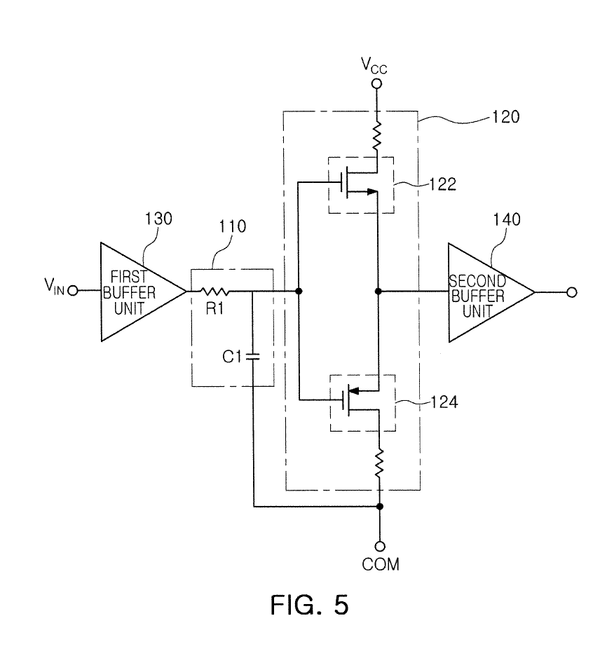

FIG. 5 is a diagram illustrating another example of the active noise filter unit illustrated in FIG. 1.

Referring to FIG. 5, the active noise filter unit 100 according to an exemplary embodiment in the present disclosure may further include a first buffer unit 130 connected between a signal input terminal Vin and the filter unit 110.

In addition, the active noise filter unit 100 may further include a second buffer unit 140 connected between the signal correcting unit 120 and a signal output terminal.

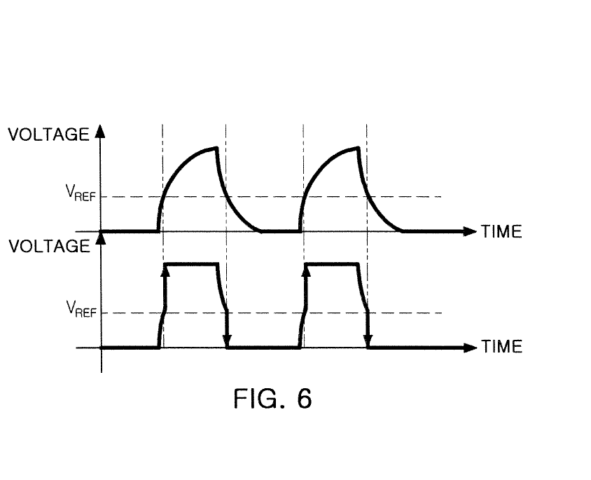

FIG. 6 is a graph illustrating a corrected input signal according to an exemplary embodiment in the present disclosure.

Referring to FIG. 6, an input signal filtered by the filter unit 110 may be formed to include a rising curve and a falling curve as illustrated in an upper graph.

Here, the signal correcting unit 120 may correct a level of the input signal to vertically increase in a case in which the level of the input signal is higher than the level of the reference voltage Vref, and may correct the level of the input signal to vertically decrease in a case in which the level of the input signal is lower than the level of the reference voltage Vref, such that the active noise filter unit 100 may output the input signal as illustrated in a lower graph.

As set forth above, according to exemplary embodiments in the present disclosure, since the input signals may not overlap even in the case continuous input thereof, by correcting the level of the input signal based on the level of the input signal, noise may be filtered, whereby damage to the inverter due to the over-current may be prevented.

While exemplary embodiments have been shown and described above, it will be apparent to those skilled in the art that modifications and variations could be made without departing from the scope of the present invention as defined by the appended claims.

What is claimed is:

1. A gate driving device, comprising:
an active noise filter unit configured to filter noise included in an input signal and correct a filtered input signal based on a level of the filtered input signal;
a level shift unit configured to convert a level of a corrected input signal to a preset level; and
a gate driving unit configured to output a switching control signal based on a converted level of the input signal.

2. The gate driving device of claim 1, wherein the active noise filter unit includes:
a filter unit configured to filter noise included in the input signal; and
a signal correcting unit configured to correct the filtered input signal based on a level of the filtered input signal.

3. The gate driving device of claim 2, wherein the signal correcting unit outputs a high signal in a case in which the level of the filtered input signal is higher than a level of a preset reference voltage, and outputs a low signal in a case in which the level of the filtered input signal is lower than the level of the preset reference voltage.

4. The gate driving device of claim 2, wherein the signal correcting unit includes:
a first transistor having the filtered input signal provided to a gate thereof, and switched on in a case in which the level of the filtered input signal is higher than a level of a preset reference voltage; and
a second transistor coupled to the first transistor in a cascode manner, having the filtered input signal provided to a gate thereof, and switched off in the case in which the level of the filtered input signal is higher than the level of the preset reference voltage.

5. The gate driving device of claim 2, wherein the signal correcting unit includes a comparator comparing the level of the filtered input signal with a level of a preset reference voltage.

6. The gate driving device of claim 2, wherein the active noise filter unit further includes a first buffer connected between a signal input terminal and the filter unit.

7. The gate driving device of claim 2, wherein the active noise filter unit further includes a second buffer connected between the signal correcting unit and the level shift unit.

8. The gate driving device of claim 2, wherein the filter unit is a resistor-capacitor (RC) filter.

9. An active noise filter, comprising:
a filter unit configured to filter noise included in an input signal; and
a signal correcting unit configured to correct the filtered input signal based on a level of the filtered input signal.

10. The active noise filter of claim 9, wherein the signal correcting unit outputs a high signal in a case in which the level of the filtered input signal is higher than a level of a preset reference voltage, and outputs a low signal in a case in which the level of the filtered input signal is lower than the level of the preset reference voltage.

11. The active noise filter of claim 10, wherein the signal correcting unit includes:
a first transistor having the filtered input signal provided to a gate thereof, and switched on in the case in which the filtered input signal is higher than the level of the preset reference voltage; and
a second transistor coupled to the first transistor in a cascode manner, having the filtered input signal provided to a gate thereof, and switched off in the case in which the filtered input signal is higher than the level of the preset reference voltage.

12. The active noise filter of claim 10, wherein the signal correcting unit includes a comparator comparing the level of the filtered input signal with the level of the preset reference voltage.

13. The active noise filter of claim 9, further comprising a first buffer connected between a signal input terminal and the filter unit.

14. The active noise filter of claim 9, further comprising a second buffer connected between the signal correcting unit and a signal output terminal.

15. The active noise filter of claim 9, wherein the filter unit is a resistor-capacitor (RC) filter.
